(19) United States
(12) Patent Application Publication
(10) Pub. No.: US 2008/0001179 A1
(43) Pub. Date: Jan. 3, 2008

(54) Back-lit image sensor

(75) Inventor: Francois Roy, Seyssins (FR)

Correspondence Address: STMicroelectronics Inc.;c/o WOLF, GREENFIELD & SACKS, P.C., 600 Atlantic Avenue, BOSTON, MA, 02210-2206, US

(73) Assignee: STMicroelectronics S.A., Montrouge (FR)

(21) Appl. No.: 11/821,902

(22) Filed: Jun. 26, 2007

(30) Foreign Application Priority Data
Jun. 28, 2006 (FR) FR06/52682

(51) Int. Cl. H01L 31/113; H01L 31/18

(52) U.S. Cl. 257/228; 438/60; 257/E31.084; 257/E31.126

(57) ABSTRACT

An image sensor including a substrate of a semiconductor material having first and second opposite surfaces; at least one photodiode formed in the substrate on the first surface side and intended to be lit through the second surface; a stacking of insulating layers covering the first surface; and conductive regions formed at the stacking level. The sensor further includes a transparent insulating layer at least partly covering the second surface; a transparent conductive layer at least partly covering the transparent insulating layer; and circuitry for biasing the conductive layer.

### BACKGROUND OF THE INVENTION

1. Field of the Invention

The present invention relates to an image sensor made in monolithic form capable of being used in shooting devices such as, for example, film cameras, camcorders, digital microscopes, or again digital photographic cameras. More specifically, the present invention relates to a photosensitive cell based on semiconductors.

2. Discussion of the Related Art

FIG. 1 schematically illustrates an example of a circuit of a photosensitive cell of an array of photosensitive cells of an image sensor. With each photosensitive cell of the array is associated a precharge device and a read device. The precharge device is formed of an N-channel MOS transistor M₁, interposed between a supply rail Vdd and a read node S. The gate of precharge transistor M₁ is capable of receiving a precharge control signal RST. The read device is formed of the series connection of first and second N-channel MOS transistors M₂, M₃. The drain of first read transistor M₂ is connected to supply rail Vdd. The source of second read transistor M₃ is connected to an input terminal P of a processing circuit (not shown). The gate of first read transistor M₂ is connected to read node S. The gate of second read transistor M₃ is capable of receiving a read signal RD. The photosensitive cell comprises a charge storage diode D₁ having its anode connected to a reference supply rail or circuit ground GND and its cathode directly connected to node S. The photosensitive cell comprises a photodiode D₂ having its anode connected to reference supply rail GND and its cathode connected to node S via an N-channel MOS charge transfer transistor M₄. The gate of transfer transistor M₄ is capable of receiving a charge transfer control signal T. Generally, signals RD, RST, and T are provided by control circuits not shown in FIG. 1 and may be provided to all the photosensitive cells of a same row of the cell array. Diode D₁ may be formed other than by a specific component. The function of storing the charges originating from photodiode D₂ is then ensured by the apparent capacitance at read node S which is formed of the source capacitances of transistors M₁ and M₄, of the input capacitance of transistor M₂, as well as on all the stray capacitances present at node S.

The operation of this circuit will now be described. A photodetection cycle starts with a precharge phase during which a reference voltage level is imposed to diode D₁. This precharge is performed by maintaining second read transistor M₃ off and by turning on precharge transistor M₁. Once the precharge has been performed, precharge transistor M₁ is off. Then, the system is maintained as such, all transistors being off. Some time after the end of the precharge, the state at node S, that is, the real reference charge state of diode D₁, is read. To evaluate the charge state, second read transistor M₃ is turned on for a very short time. The cycle carries on with a transfer to node S of the photogenerated charges, that is, those created and stored in the presence of a radiation, in photodiode D₂. This transfer is performed by turning on transfer transistor M₄. Once the transfer is over, transistor M₄ is turned off, and photodiode D₂ starts photogenerating and storing charges which will be subsequently transferred to node S. Simultaneously, at the end of the transfer, the new charge state of diode D₂ is read. The output signal transmitted to terminal P then depends on the channel pinch of first read transistor M₂, which is a direct function of the charge stored in the photodiode.

Conventionally, when the image sensor is made in monolithic form, photodiodes D₂ and transistors M₁ to M₄ of each photosensitive cell are formed at the level of a silicon substrate covered with a stack of insulating layers. Metal tracks and vias are formed at the level of the stack of insulating layers and are connected to the components of the photosensitive cells. Lenses are distributed on the upper surface of the stack of insulating layers, each lens being associated with a photosensitive cell and ensuring the focusing of the light rays reaching the upper surface of the image sensor on the photodiode of the associated photosensitive cell.

A disadvantage of such a structure is that the straight travel of the light rays from each lens to the associated photodiode may be hindered by the metal tracks and vias present at the level of the stacking of insulating layers covering the substrate. It may then be necessary to provide additional optical devices, in addition to the previously-mentioned lenses, to ensure that most of the light rays which reach the upper surface of the image sensor reach the photodiodes of the photosensitive cells. This results in image sensors that may have a relatively complex structure, and are difficult to form.

A solution to avoid use of additional optical devices comprises lighting the image sensor through the rear surface of the substrate at the level of which the photodiodes are formed. The image sensor is then said to be back-lit.

FIGS. 2A to 2F illustrate an example of a conventional method for manufacturing a back-lit image sensor.

FIG. 2A shows an SOI-type structure (silicon on insulator) comprising a support 10, for example, a silicon wafer, covered with an insulating layer 12, and with a lightly-doped P-type silicon layer 14, which will be called substrate hereinafter. Layer 14 has a thickness on the order of a few micrometers.

FIG. 2B shows the structure obtained after having formed the photosensitive cell components. As an example, photodiodes D2 and transistors M4 of two adjacent cells are shown in FIG. 2B. Each cell is delimited by field insulation regions 20, for example, made of silicon oxide, each surrounded with a P-type region 22 more heavily doped than substrate 14. Each photodiode D2 is formed at the level of an N-type region 24. In the case where photodiodes of completely depleted type are used, each region 24 is covered with a P-type region 26 more heavily doped than substrate 14. An N-type region 28, formed in substrate 14, corresponds to the drain region of transistor M4. An insulating portion 30 extends, on substrate 14, between regions 28 and 24 and corresponds to the gate oxide of transistor M4. Insulating portion 30 is covered with a polysilicon portion 32 corresponding to the gate of transistor M4. Substrate 14 is covered with a stack of insulating layers, three insulating layers 34, 36, 38 being shown in FIG. 2B, at the level of which metal tracks 40 of different metallization levels and metal vias 41 enabling connection of the photosensitive cell components are formed.

FIG. 2C shows the structure obtained after having glued, on the upper surface of last insulating layer 38, a stiffening element formed, for example, of the stacking of an insulating layer 42 and of a silicon wafer 43.

FIG. 2D shows the structure obtained after a “thinning” step which comprises removing, for example by chemical or chem./mech. etch, support 10 and insulating layer 12 to expose rear surface 44 of substrate 14. After the thinning step, defects in the crystal structure at the level of rear surface 44 which favor the forming of electron/hole pairs of thermal origin can be observed in substrate 14. In the absence of specific processings, such electrons of thermal origin are likely to be captured by the photodiodes of the image sensor, causing a disturbance of the signals read from the read nodes of the photosensitive cells. The disturbances due to thermal electrons are generally called “dark current” disturbances.

FIG. 2E shows the structure obtained after having performed an implantation at the level of rear surface 44 of substrate 14 and an activation anneal enabling reconstructing the crystal lattice, which results in the forming of a P-type region 45 more heavily doped than substrate 14. Region 45 has the function of a reservoir of holes which recombine with the thermal electrons forming at the level of rear surface 44 of substrate 14 before those can diffuse to the photodiodes of the photosensitive cells. Region 45 should be as thin as possible to avoid altering the sensitivity of the image sensor.

FIG. 2F shows the structure obtained after having formed on rear surface 44 of substrate 14 colored filters 46, 48, in the case of a color sensor, and lenses 50, 52 associated with each photosensitive cell of the image sensor.

According to a variation of the previously-described conventional image sensor manufacturing method, instead of using a silicon-on-insulator or SOI structure, such as shown in FIG. 2A, a solid heavily-doped P-type silicon wafer on which lightly-doped P-type layer 14 is formed by epitaxy may be used. At step 2E, the solid silicon wafer is removed, for example, by etching, and the etch stop can be obtained by playing on the selectivity differences between the solid heavily-doped silicon wafer and lightly-doped epitaxial layer 14. The next method steps are identical to what has been described previously in relation with FIGS. 2E and 2F.

The main disadvantage of previously-described conventional methods for manufacturing image sensors is due to the activation anneal step, which results in the forming of heavily-doped P-type region 45. Indeed, the activation anneal is obtained by heating the image sensor up to temperatures generally greater than 600-700° C. and is performed after forming of insulating layers 34, 36, 38, of metal tracks 40, and of vias 41. Such temperatures may be incompatible with the metallic and dielectric materials conventionally used in CMOS technologies for the forming of metal tracks 40, of vias 41, and of insulating layers 34, 36, 38.

A solution includes performing the activation anneal by local heating of substrate 14, for example by scanning rear surface 44 with a laser beam. The local heating of rear surface 44 of substrate 14 avoids propagating the heat to the rest of the image sensor, especially to the stack of insulating layers 34, 36, 38. However, a disadvantage is that the operation of sweeping with a laser beam tends to leave “marks” at the level of rear surface 44 of substrate 14, which translate as visible marks on the images provided by the image sensor.

Another solution includes using specific materials accepting high temperatures, for example, refractory materials, to form metal tracks 40, vias 41, and insulating layers 34, 36, 38. A disadvantage is that the image sensor manufacturing process is then no longer compatible with conventional CMOS technology methods. This is not desirable, in particular when the image sensor is formed on a portion of an integrated circuit, the rest of which is occupied by components capable of being formed according to conventional CMOS technology methods.

### SUMMARY OF THE INVENTION

A feature of at least one embodiment of the present invention is a back-lit image sensor enabling a decrease, or even elimination of dark current disturbances due to electrons of thermal origin forming at the rear surface, and which is capable of being formed by a method compatible with CMOS technologies.

According to another feature of at least one embodiment of the present invention, the image sensor structure is little modified with respect to a conventional back-lit image sensor.

A feature of at least one embodiment of the present invention is a method for manufacturing a back-lit image sensor enabling a decrease or even elimination of dark current disturbances due to thermal electrons forming at the rear surface level, and which is compatible with CMOS technologies.

To achieve all or part of these features, as well as others, one embodiment of the present invention provides an image sensor comprising a substrate of a semiconductor material comprising first and second opposite surfaces; at least one photodiode formed in the substrate on the first surface side and intended to be lit through the second surface; a stack of insulating layers covering the first surface; and conductive regions formed at the stack level. The image sensor further comprises a transparent insulating layer at least partly covering the second surface; a transparent conductive layer at least partly covering the transparent insulating layer; and means for biasing the conductive layer.

According to an example of embodiment of the present invention, the transparent conductive layer is based on metal oxide.

According to an example of embodiment of the present invention, the transparent conductive layer is based on indium and tin oxide.

According to an example of embodiment of the present invention, the transparent conductive layer has a thickness smaller than 500 nm.

According to an example of embodiment of the present invention, the transparent insulating layer has a thickness smaller than 200 nm.

Another embodiment of the present invention provides an optical device, especially a film camera, a camcorder, a digital microscope, or a digital photographic camera, comprising an image sensor such as described hereabove.

Another embodiment of the present invention provides a method for manufacturing an image sensor, comprising the steps of:
(a) providing a substrate of a semiconductor material comprising first and second opposite surfaces;
(b) forming, in the substrate, at least one photodiode on the first surface side;
(c) forming on the first surface a stack of insulating layers and forming conductive regions at the stack level;
(d) forming a transparent insulating layer on at least a portion of the second surface; and
(e) forming a transparent conductive layer on at least a portion of the transparent insulating layer, means for biasing the conductive layer being formed after step (e) or at least at one of steps (a) to (e).

According to an example of embodiment of the present invention, at step (a), the substrate is formed on a support and step (d) is preceded by a step comprising the support removal.

According to an example of embodiment of the present invention, at step (a), the substrate is formed on an insulating region covering a support, and step (d) comprises removing the support, the transparent insulating layer corresponding to the insulating region, or removing the support and a portion of the insulating region, the insulating layer corresponding to the remaining portion of the insulating region.

The foregoing and other objects, features, and advantages of the present invention will be discussed in detail in the following non-limiting description of specific embodiments in connection with the accompanying drawings.

### BRIEF DESCRIPTION OF THE DRAWINGS

FIG. 1, previously described, shows an electric diagram of a photosensitive cell;

FIGS. 2A to 2F, previously described, illustrate the successive steps of a conventional method for manufacturing a back-lit image sensor;

FIGS. 3A to 3C illustrate steps of an example of a method for manufacturing a back-lit image sensor according to at least one embodiment of the present invention; and

FIG. 4 is a detail view of the image sensor of FIG. 3C illustrating the operation of the image sensor according to the present invention; and

FIG. 5 very schematically shows a cell phone comprising an image sensor according to the present invention.

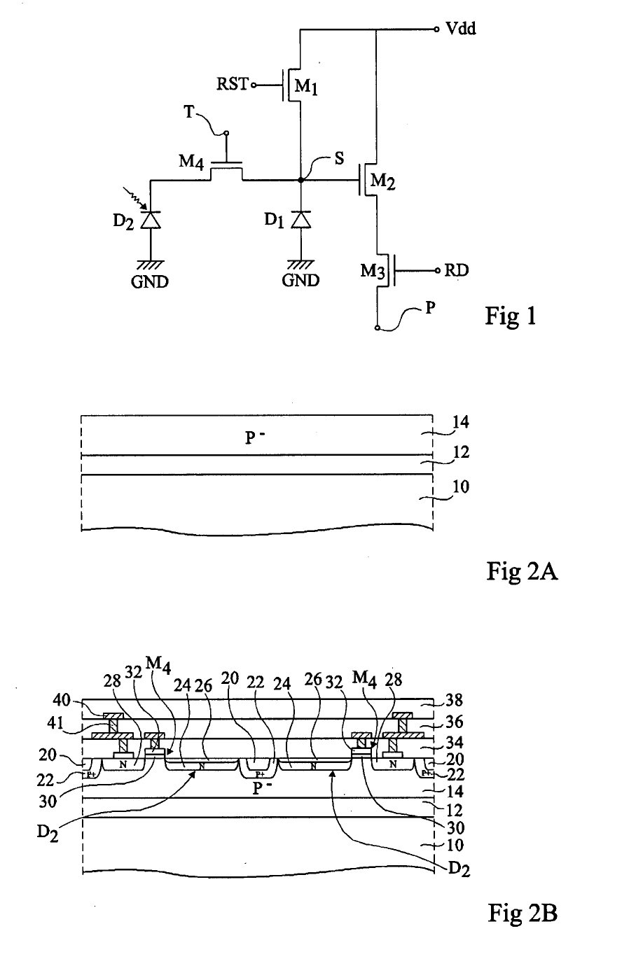

### DETAILED DESCRIPTION

For clarity, the same elements have been designated with the same reference numerals in the different drawings and, further, as usual in the representation of integrated circuits, the various drawings are not to scale.

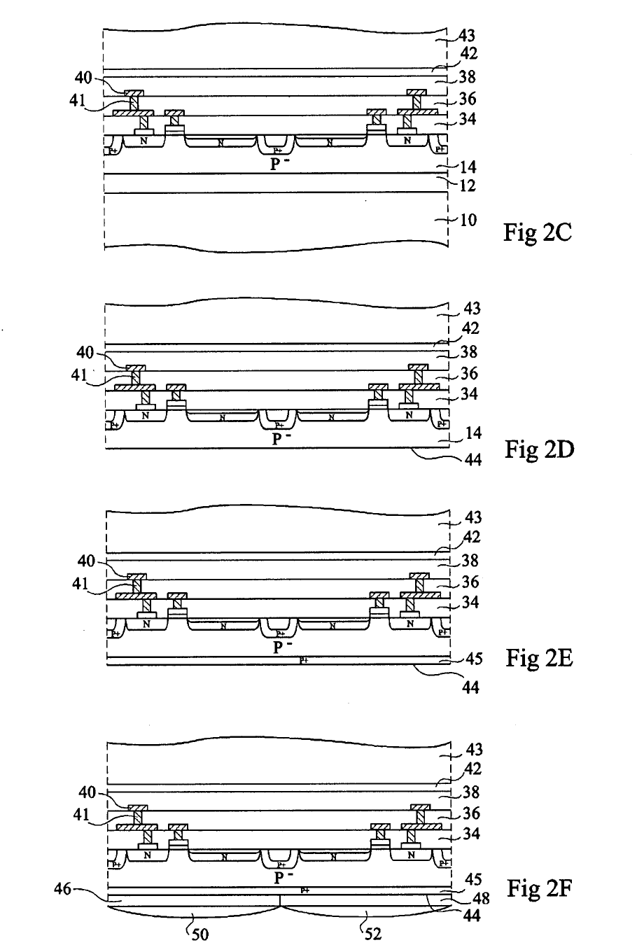

An example of a method for manufacturing an image sensor or photodetector according to the present invention will now be described. As an example, it is started from a structure of silicon-on-insulator type such as shown in FIG. 2A.

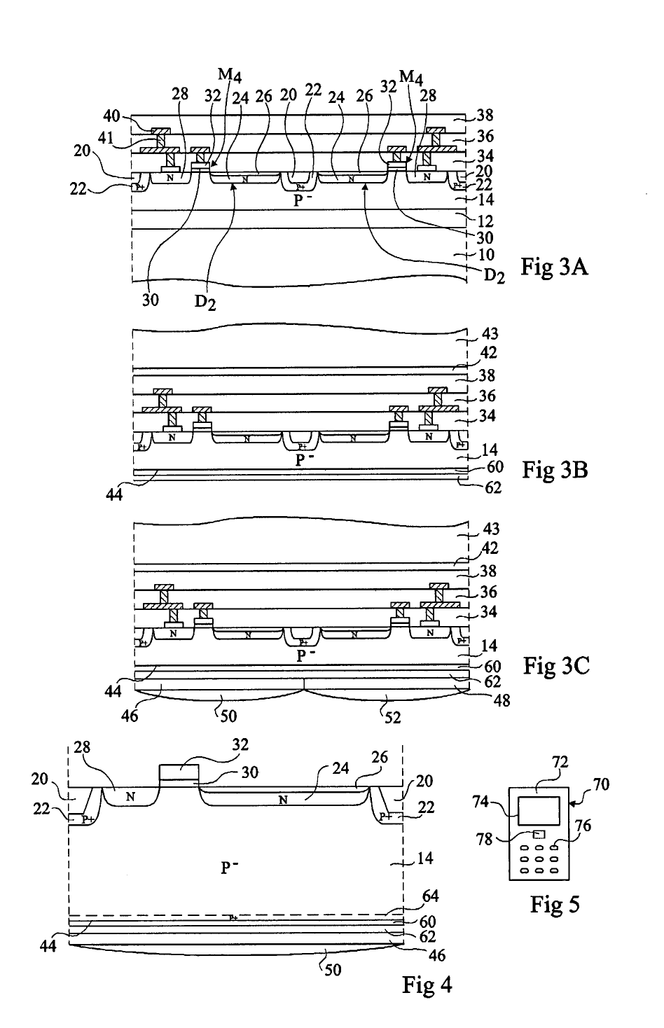

FIG. 3A is a drawing similar to FIG. 2B and shows the structure obtained after having formed the photosensitive cell components, the stack of insulating layers 34, 36, 38, metal tracks 40, and metal vias 41. The next steps of the example of the method according to the present invention correspond to the steps of the conventional method for manufacturing of an image sensor previously described in relation with FIG. 2C.

FIGS. 3B and 3C illustrate the last steps of the example of a manufacturing method according to at least one embodiment of the present invention.

FIG. 3B illustrates the structure obtained after having deposited, on rear surface 44 of substrate 14, a transparent insulating layer 60 covered with a transparent conductive layer 62. As an example, insulating layer 60 has a thickness smaller than 200 nm, for example, approximately 20 nm, and is formed of silicon oxide, and conductive layer 62 has a thickness smaller than 500 nm, for example, approximately 200 nm, and is based on metal oxide, for example, based on indium tin oxide or ITO. Insulating layer 60 may be formed by low-temperature deposition on substrate 14.

According to a variation of the present invention, insulating layer 60 may correspond to insulating layer 12. In this case, in the “thinning” step, only support 10 is removed. When support 10 is removed by etching, insulating layer 12 may be used as an etch stop layer. According to another variation, insulating layer 60 may correspond to a portion of insulating layer 12. In this case, in the “thinning” step, support 10 is removed and a portion only of insulating layer 60 is removed.

FIG. 3C shows the structure obtained after having formed filters 46, 48 and lenses 50, 52 similarly to what has been previously described in relation with FIG. 2F. At the image sensor periphery, metal contacts, not shown, distributed on the lit surface of the image sensor and connected to conductive layer 62 are provided. Such metal contacts are, in operation, connected to a source of a bias voltage of conductive layer 62.

As compared with the conventional method for manufacturing an image sensor previously described in relation with FIGS. 2A to 2F, the steps of implantation at rear surface 44 and of activation anneal intended to form heavily-doped P-type region 45 have been replaced, in the present example of a method for manufacturing the image sensor according to the present invention with the steps of depositing on rear surface 44 a transparent insulating layer 60 covered with a transparent conductive layer 62. Steps of forming of means for biasing conductive layer 62 have further been provided. Such steps may be carried out at temperatures which are compatible with the materials conventionally used in CMOS technologies. The example of a manufacturing method according to the present invention is thus compatible with CMOS technologies.

FIG. 4 is a detail view of FIG. 3C when conductive layer 62 is properly biased. The forming, in substrate 14 at the at the contact of insulating layer 60, of a region 64 having an increased hole concentration, region 64 being delimited in FIG. 4 by a dashed line is indeed obtained. Region 64 then plays the role of a hole reservoir, ensuring a quasi-immediate recombination of thermal electrons due to the crystal structure defects at the level of rear surface 44 of substrate 14. The thickness of region 64 may be controlled by the bias voltage applied to conductive layer 62, for example, on the order of from −1 to −3 volts.

FIG. 5 illustrates an example of the use of the image sensor according to the present invention. FIG. 5 very schematically shows a cell phone 70 comprising a package 72 at the level of which are arranged a screen 74 and a keyboard 76. Cell phone 70 also comprises an image acquisition system 78 comprising an optical system directing the light rays towards an image sensor according to the present invention.

Of course, the present invention is likely to have various alterations, modifications, and improvements which will readily occur to those skilled in the art. In particular, the present invention also applies to a photosensitive cell for which several photodiodes are connected to a same read node. Further, although the present invention has been described for an image sensor cell in which the precharge device and the read device have a specific structure, the present invention also applies to a cell for which the precharge device or the read device have a different structure, for example, comprise a different number of MOS transistors.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. An image sensor comprising:
a substrate of a semiconductor material comprising first and second opposite surfaces;
at least one photodiode formed in the substrate on the side of the first surface and intended to be lit through the second surface;
a stack of insulating layers covering the first surface;
conductive regions formed at the stacking level;
a transparent insulating layer at least partly covering the second surface;
a transparent conductive layer at least partly covering the transparent insulating layer; and
means for biasing the conductive layer.

2. The image sensor of claim 1, wherein the transparent conductive layer is based on metal oxide.

3. The image sensor of claim 1, wherein the transparent conductive layer is based on indium and tin oxide.

4. The image sensor of claim 1, wherein the transparent conductive layer has a thickness smaller than 500 nm.

5. The image sensor of claim 1, wherein the transparent insulating layer has a thickness smaller than 200 nm.

6. An optical device, especially a film camera, a camcorder, a digital microscope, or a digital photographic camera, comprising the image sensor of claim 1.

7. A method for manufacturing an image sensor, comprising the steps of:
(a) providing a substrate of a semiconductor material comprising first and second opposite surfaces;
(b) forming, in the substrate, at least one photodiode on the first surface side;
(c) forming on the first surface a stack of insulating layers and forming conductive regions at the stack level;
(d) forming a transparent insulating layer on at least a portion of the second surface; and
(e) forming a transparent conductive layer on at least a portion of the transparent insulating layer, means for biasing the conductive layer being formed after step (e) or at least at one of steps (a) to (e).

8. The method of claim 7, wherein, at step (a), the substrate is formed on a support and wherein step (d) is preceded by a step comprising the support removal.

9. The method of claim 7, wherein, at step (a), the substrate is formed on an insulating region covering a support, and wherein step (d) comprises removing the support, the transparent insulating layer corresponding to the insulating region, or removing the support and a portion of the insulating region, the insulating layer corresponding to the remaining portion of the insulating region.
